(19) United States
(12) Patent Application Publication
(10) Pub. No.: US 2026/0033169 A1
(43) Pub. Date: Jan. 29, 2026

(54) DISPLAY SUBSTRATE AND DISPLAY DEVICE

(71) Applicants: CHONGQING BOE DISPLAY TECHNOLOGY CO., LTD., Chongqing (CN); BOE TECHNOLOGY GROUP CO., LTD., Beijing (CN)

(72) Inventors: Tianlong ZHAO, Beijing (CN); Wentao WANG, Beijing (CN); Lingling WANG, Beijing (CN); Teng CHEN, Beijing (CN); Weixing GONG, Beijing (CN); Faming JIANG, Beijing (CN); Liang ZHOU, Beijing (CN); Dawei SHI, Beijing (CN); Zhen LIU, Beijing (CN)

(73) Assignees: CHONGQING BOE DISPLAY TECHNOLOGY CO., LTD., Chongqing (CN); BOE TECHNOLOGY GROUP CO., LTD., Beijing (CN)

(21) Appl. No.: 18/996,741

(22) PCT Filed: Mar. 14, 2024
(86) PCT No.: PCT/CN2024/081642

§ 371 Date: Jan. 17, 2025

(30) Foreign Application Priority Data
Apr. 28, 2023 (CN) 202310478267.0

(51) Int. Cl. H10K 59/126; H10K 59/121; H10K 59/124; H10K 59/131

(52) U.S. Cl. CPC H10K 59/126; H10K 59/1213; H10K 59/124; H10K 59/131

(57) ABSTRACT

A display substrate and a display device are provided. The display substrate includes: a base substrate, a transistor structure and a shielding structure, wherein the transistor structure and the shielding structure both arranged on the base substrate, the shielding structure including a first shielding part, at least part of the first shielding part extending in a direction perpendicular to the base substrate, and an orthographic projection of the first shielding part onto the base substrate being located at a periphery of an orthographic projection of a channel part of the corresponding transistor structure on the base substrate.

### CROSS-REFERENCE TO RELATED APPLICATION

The present application claims a priority to the Chinese patent application No. 202310478267.0 filed in China on Apr. 28, 2023, a disclosure of which is incorporated herein by reference in its entirety.

### TECHNICAL FIELD

The present disclosure relates to the field of display technology, and in particular, to a display substrate and a display device.

### BACKGROUND

With the continuous development of display technology, Organic Light-Emitting Diode (OLED) display products are widely used in various fields due to their advantages of being lighter and thinner, having higher brightness, lower power consumption, faster response, higher definition, better flexibility, and higher luminous efficiency. However, when such display product is showing a white screen, and exposed to strong sunlight or intense ambient light, the display screen may experience defect of color abnormalities.

### SUMMARY

An object of the present disclosure is to provide a display substrate and a display device.

To achieve the above object, the present disclosure provides the following technical solutions.

In a first aspect of the present disclosure, it provides a display substrate, including: a base substrate, a transistor structure and a shielding structure, wherein the transistor structure and the shielding structure both arranged on the base substrate, the shielding structure including a first shielding part, at least part of the first shielding part extending in a direction perpendicular to the base substrate, and an orthographic projection of the first shielding part onto the base substrate being located at a periphery of an orthographic projection of a channel part of the corresponding transistor structure on the base substrate.

Optionally, the display substrate includes a first insulating layer located at a side of the channel part distal to the base substrate, the first insulating layer includes a first via hole, and at least part of the first shielding part is located in the first via hole.

Optionally, the display substrate includes a second insulating layer located at a side of the channel part proximate to the base substrate, the second insulating layer includes a second via hole, and at least part of the first shielding part is located in the second via hole.

Optionally, the shielding structure includes two first shielding parts, and the orthographic projection of the channel part onto the base substrate is located between the orthographic projections of the two first shielding parts onto the base substrate.

Optionally, the transistor structure includes an active layer, the active layer includes the channel part and two conductor parts, the channel part is located between the two conductor parts, and the orthographic projection of the first shielding part onto the base substrate extends in an extension direction of at least part of a boundary of an orthographic projection of the conductor part onto the base substrate.

Optionally, the orthographic projection of the channel part onto the base substrate is surrounded by the orthographic projection of the first shielding part onto the base substrate.

Optionally, the display substrate further includes a Black Shield Mask (BSM), wherein the Black Shield Mask (BSM) is located between the channel part and the base substrate, and the first shielding part is coupled to the Black Shield Mask (BSM).

Optionally, the transistor structure corresponds to at least two shielding structures, and the at least two shielding structures are sequentially arranged in a direction perpendicular to the base substrate.

Optionally, the shielding structure further includes a second shielding part, the second shielding part is coupled to the first shielding part, the second shielding part is located at the side of the first insulating layer distal to the base substrate, and at least part of an orthographic projection of the second shielding part onto the base substrate is located at the periphery of the orthographic projection of the channel part onto the base substrate.

Optionally, the orthographic projection of the second shielding part onto the base substrate overlaps at least partially with the orthographic projection of the channel part onto the base substrate.

Optionally, the transistor structure includes a gate layer, and at least part of the gate layer is reused as the second shielding part.

Optionally, the display substrate further includes a power line, and at least part of the power line is reused as the second shielding part.

Optionally, the display substrate includes a first gate insulating layer, a first gate metal layer, a second gate insulating layer, a second gate metal layer, an interlayer insulating layer, a first source-drain metal layer, a passivation layer, a first planarization layer, a second source-drain metal layer, a second planarization layer and an anode layer that are laminated sequentially in that order on the base substrate in a direction away from the base substrate; the channel part is located between the first gate insulating layer and the base substrate;

the second shielding part is arranged in a same layer and made of a same material as at least one of the first gate metal layer, the second gate metal layer, the first source-drain metal layer, the second source-drain metal layer or the anode layer.

Optionally, the first shielding part and the second shielding part are formed as an integrated structure.

Optionally, the first insulating layer includes at least one of the first gate insulating layer, the second gate insulating layer, the interlayer insulating layer, the passivation layer, the first planarization layer or the second planarization layer.

Optionally, the second shielding part is arranged in a same layer and made of a same material as the first gate metal layer, the first insulating layer includes the first gate insulating layer, and the first via hole penetrates through the first gate insulating layer.

Optionally, the second shielding part is arranged in a same layer and made of a same material as the second gate metal layer, the first insulating layer includes the first gate insulating layer and the second gate insulating layer, and the first via hole penetrates through the first gate insulating layer and the second gate insulating layer.

Optionally, the second shielding part is arranged in a same layer and made of a same material as the first source-drain metal layer, the first insulating layer includes the first gate insulating layer, the second gate insulating layer and the interlayer insulating layer, and the first via hole penetrates through the first gate insulating layer, the second gate insulating layer and the interlayer insulating layer.

Optionally, the second shielding part is arranged in a same layer and made of a same material as the second source-drain metal layer, the first insulating layer includes the first planarization layer, and the first via hole penetrates through the first planarization layer.

Optionally, the second shielding part is arranged in a same layer and made of a same material as the anode layer, the first insulating layer includes the first planarization layer and the second planarization layer, and the first via hole penetrates through the first planarization layer and the second planarization layer.

Optionally, the display substrate includes a plurality of sub-pixels, the sub-pixels include a sub-pixel driving circuit and a light-emitting element, the light-emitting element includes an anode pattern, the sub-pixel driving circuit is coupled to the anode pattern; the sub-pixel driving circuit includes the transistor structure.

Optionally, the anode pattern is reused as the second shielding part.

In a second aspect of the present disclosure, based on the technical solutions of the display substrate, it provides a display device, including the above display substrate.

### BRIEF DESCRIPTION OF THE DRAWINGS

The accompanying drawings described herein are provided to further illustrate the present disclosure, forming a part thereof. The illustrative embodiments and descriptions of the present disclosure are intended to explain the present disclosure and do not constitute undue limitations on it. In the drawings:

FIG. 1 is a circuit structure diagram of a sub-pixel driving circuit provided in an embodiment of the present disclosure;

FIG. 2 is a first cross-sectional schematic diagram of a transistor structure and a shielding structure provided in an embodiment of the present disclosure;

FIG. 3 is a second cross-sectional schematic diagram of a transistor structure and a shielding structure provided in an embodiment of the present disclosure;

FIG. 4 is a third cross-sectional schematic diagram of a transistor structure and a shielding structure provided in an embodiment of the present disclosure;

FIG. 5 is a fourth cross-sectional schematic diagram of a transistor structure and a shielding structure provided in an embodiment of the present disclosure;

FIG. 6 is a fifth cross-sectional schematic diagram of a transistor structure and a shielding structure provided in an embodiment of the present disclosure;

FIG. 7 is a sixth cross-sectional schematic diagram of a transistor structure and a shielding structure provided in an embodiment of the present disclosure;

FIG. 8 is a seventh cross-sectional schematic diagram of a transistor structure and a shielding structure provided in an embodiment of the present disclosure;

FIG. 9 is a first schematic diagram of a projection of a first shielding part and an active layer onto a base substrate provided in an embodiment of the present disclosure;

FIG. 10 is a second schematic diagram of a projection of a first shielding part and an active layer onto a base substrate provided in an embodiment of the present disclosure.

### DETAILED DESCRIPTION

To further illustrate the display substrate and the display device provided by the embodiments of the present disclosure, a detailed description will be given below in conjunction with the accompanying drawings.

In the related art, in the case that a display product is in high-brightness mode showing a white screen, when it is exposed to sunlight or strong light from a flashlight at an oblique angle, such as when an incident light direction forms an angle of less than 45° relative to a horizontal direction of a display screen (i.e., large-angle light incidence), the color abnormality of the display screen intensifies. The color abnormality includes the irradiated area being pink, purple, etc., and a display area where color abnormality occurs returns to normal once the light exposure ceases.

Research has found that a transistor structure is located beneath the display screen, which includes a channel part; when strong light passes through the display screen and shines onto the channel part, a photoelectric effect occurs in the channel part, causing the transistor structure characteristics to shift and the leakage current to increase. When the transistor structure is applied to a green sub-pixel as a compensation transistor, the photoelectric effect will cause the leakage current of the green sub-pixel to be greater than that of the red and blue sub-pixels. This leads to the green light brightness of the green sub-pixel to decrease, causing the area illuminated by strong light under the white screen to appear pink and purple. At the same time, when strong light is irradiated obliquely, the light enters the channel part from the side, causing the reddish and purple phenomena of the display product to increase. At the same time, light incident at an oblique angle is reflected into the channel part by the film layer between the channel part and the substrate base (e.g., a Black Shield Mask (BSM)), which further aggravates the photoelectric effect.

Referring to FIGS. 2 to 8, the embodiments of the present disclosure provide a display substrate, including: a base substrate 10, a transistor structure TFT and a shielding structure 20, wherein the transistor structure TFT and the shielding structure 20 are both arranged on the base substrate 10, the shielding structure 20 includes a first shielding part 201, at least part of the first shielding part 201 extending in a direction perpendicular to the base substrate 10, and an orthographic projection of the first shielding part 201 onto the base substrate 10 is located at a periphery of an orthographic projection of a channel part 301 of the corresponding transistor structure TFT on the base substrate 10.

For example, the transistor structure TFT includes an active layer 30 and a gate layer GT, a first gate insulating layer GI1 is arranged between the gate layer GT and the active layer 30, and there is an overlapping region between an orthographic projection of the gate layer GT onto the base substrate 10 and an orthographic projection of the active layer 30 onto the base substrate 10, and the part of the active layer 30 located in the overlapping region is the channel part 301 of the transistor structure TFT. The channel part 301 includes a semiconductor part.

For example, the channel part 301 is made of a polysilicon material, but the present disclosure not limited thereto.

For example, the channel part 301 is made of an oxide material, but the present disclosure not limited thereto.

For example, the shielding structure 20 may be made of a metal material with high reflectivity.

As shown in Table 1, Table 1 illustrates the reflectivity of various metal film layers for light at different wavelengths. From the reflectivity data of each metal film layer for visible light in Table 1, it can be observed that Ag and Al have higher reflectivity for visible light (taking 500 nm visible light as an example), so the shielding structure 20 may be made of metal materials such as Ag and Al, but the present disclosure is not limited thereto.

TABLE 1

Reflectivity of light at different wavelengths

| Item | 500 nm | 650 nm | 800 nm |
|---|---|---|---|
| Ag | 97.9% | 98.8% | 99.2% |
| Al | 91.8% | 90.5% | 88.7% |
| Ti | 56.6% | 59.0% | |
| Mo | 46% | | |

For example, at least part of the first shielding part 201extendes in a direction perpendicular to the substrate 10, and the length of the part in a direction perpendicular to the substrate 10 is greater than a first threshold value, and the first threshold value ensures that the first shielding part 201 blocks more than 90% of the light entering the channel part 301 from the side.

For example, at least part of the first shielding part 201 is located at the side of the channel part 301 distal to the base substrate 10.

For example, the first shielding part 201 includes a part that is on the same plane as the channel part 301.

For example, the first shielding part 201 includes a part located at the side of the channel part 301 proximate to the base substrate 10.

For example, the distance between the orthographic projection of the first shielding part 201 onto the base substrate 10 and the orthographic projection of the channel part 301 onto the base substrate 10 is less than a second threshold value, and the second threshold value ensures that the first shielding part 201 blocks more than 90% of the light entering the channel part 301 from the side.

For example, a cross-sectional area of the first shielding part 201 in the direction perpendicular to the base substrate 10 is greater than a third threshold value, and the third threshold value ensures that the first shielding part 201 blocks more than 90% of the light entering the channel part 301 from the side.

For example, the display substrate includes a reflective layer located between the channel part 301 and the base substrate 10, and the orthographic projection of the first shielding part 201 onto the base substrate 10 is located at a periphery of an orthographic projection of the reflective layer onto the base substrate 10.

According to the specific structure of the display substrate described above, in the display substrate provided by the embodiments of the present disclosure, the shielding structure 20 includes the first shielding part 201, at least part of the first shielding part 201 extends in a direction perpendicular to the base substrate 10, and the orthographic projection of the first shielding part 201 onto the base substrate 10 is located at the periphery of the orthographic projection of the channel part 301 of the corresponding transistor structure TFT onto the base substrate 10. The above-mentioned arrangement enables the first shielding part 201 to shield the channel part 301, especially increasing the shielding of light incident at large oblique angles, thus reducing the exposure of the channel part 301 to external light and improving its photoelectric effect. Additionally, since the first shielding part 201 extends in a direction perpendicular to the substrate 10, it does not affect the transmittance of the display substrate.

In the display substrate provided by the embodiments of the present disclosure, when the transistor structure TFT is applied to the green sub-pixel as a compensation transistor, it prevents the problem of the leakage current of the green sub-pixel being greater than that of the red sub-pixel and the blue sub-pixel due to the photoelectric effect. This ensures the green light brightness of the green sub-pixel, and avoids the problem such as the area appearing pink or purple under strong light in the white screen of the display substrate. In the display substrate provided by the embodiments of the present disclosure, when the strong light is irradiated obliquely, the light will not enter the channel part 301 from the side, avoiding the problem of aggravation of the reddish and purple phenomenon of the display product. At the same time, in the display substrate provided by the embodiments of the present disclosure, it is possible to prevent the obliquely irradiated light from irradiating the film layer (such as Black Shield Mask (BSM)) located between the channel part 301 and the base substrate 10, and avoid the light from entering the channel part 301 after being reflected by the film layer, which further avoids the photoelectric effect of the channel part 301.

Referring to FIGS. 2 to 8, in some embodiments of the present disclosure, the display substrate includes a first insulating layer (such as at least one of a first gate insulating layer GI1, a second gate insulating layer GI2, an interlayer insulating layer ILD, a passivation layer PVX, a first planarization layer PLN1, and a second planarization layer PLN2) located at the side of the channel part 301 distal to the base substrate 10, the first insulating layer includes a first via hole, and at least part of the first shielding part 201 is located in the first via hole.

For example, the first via hole penetrates through the first insulating layer, and the part of the first shielding part 201 located in the first via hole extends in a direction perpendicular to the base substrate 10.

As shown in FIGS. 7 and 8, in some embodiments of the present disclosure, the display substrate includes a second insulating layer GO located at the side of the channel part 301 proximate to the base substrate 10, the second insulating layer GO includes a second via hole, and at least part of the first shielding part 201 is located in the second via hole.

For example, the second via hole penetrates through the second insulating layer GO, and the part of the first shielding part 201 located in the second via hole extends in a direction perpendicular to the base substrate 10.

In the display substrate provided by the above embodiments, the first shielding part 201 is arranged in the first via hole and/or the second via hole, which not only ensures the shielding performance of the first shielding part 201, but also avoids the first shielding part 201 from extending over a large area in a direction parallel to the base substrate 10, thereby avoiding affecting the transmittance of the display substrate.

As shown in FIGS. 2 to 8, in some embodiments of the present disclosure, the shielding structure 20 includes two first shielding parts 201, and the orthographic projection of the channel part 301 onto the base substrate 10 is located between the orthographic projections of the respective two first shielding parts 201 onto the base substrate 10.

For example, the shielding structure 20 includes at least two first shielding parts 201, and the orthographic projections of the at least two shielding parts onto the base substrate 10 are arranged around the periphery of the orthographic projection of the channel part 301 onto the base substrate 10.

In the above-mentioned arrangement, it enables the first shielding part 201 to block light that is from all directions around the channel part 301 and directed toward the channel part 301, thus better preventing the occurrence of the photoelectric effect in the channel part 301.

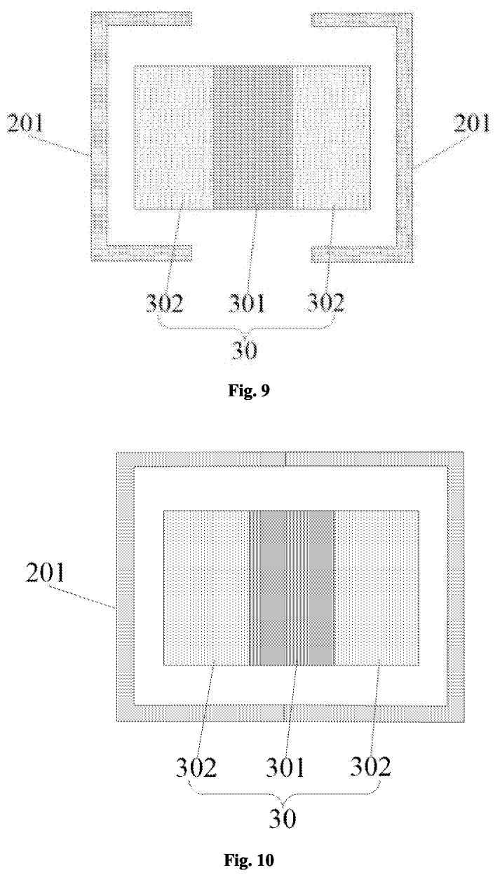

As shown in FIGS. 2 to 8 and FIG. 9, in some embodiments of the present disclosure, the transistor structure TFT includes an active layer 30, and the active layer 30 includes the channel part 301 and two conductor parts 302, at least part of the channel part 301 is located between the two conductor parts 302, and the orthographic projection of the first shielding part 201 onto the base substrate 10 extends in the extension direction of at least part of the boundary of the orthographic projection of the conductor part 302 onto the base substrate 10.

For example, the orthographic projection of the first shielding part 201 onto the base substrate 10 is adjacent to the orthographic projection of the conductor part 302 onto the base substrate 10.

For example, the orthographic projection of the first shielding part 201 onto the base substrate 10 overlaps at least partially with the orthographic projection of the conductor part 302 onto the base substrate 10.

The above-mentioned arrangement enables the first shielding part 201 to block light from all directions around the channel part 301 and directed toward the channel part 301, thus better preventing the occurrence of the photoelectric effect in the channel part 301.

As shown in FIG. 10, in some embodiments of the present disclosure, the orthographic projection of the channel part 301 onto the base substrate 10 is surrounded by the orthographic projection of the first shielding part 201 onto the base substrate 10.

The above-mentioned arrangement enables the first shielding part 201 to block light from all directions around the channel part 301 and directed toward the channel part 301, thus better preventing the occurrence of the photoelectric effect in the channel part 301.

As shown in FIGS. 7 and 8, in some embodiments of the present disclosure, the display substrate further includes a Black Shield Mask (BSM), the Black Shield Mask (BSM) is located between the channel part 301 and the base substrate 10, and the first shielding part 201 is coupled to the Black Shield Mask (BSM).

For example, the display substrate further includes a power line VDD, the power line VDD is located at the side of the first shielding part 201 distal to the base substrate 10, and the first shielding part 201 is coupled to each of the power line VDD and the Black Shield Mask (BSM).

For example, a via hole process is used to form a via hole in the insulating layer between the power line VDD and the Black Shield Mask (BSM), and at least part of the first shielding part 201 is located in the via hole. In this way, the power line VDD may also function as a light shield for the compensation part.

For example, the compensation part corresponds to two first shielding parts 201, the two power lines VDD coupled to the two first shielding parts 201 are adjacent, and the orthographic projection of the channel part 301 onto the base substrate 10 is located between the orthographic projections of the two power lines VDD onto the base substrate 10.

The coupling of the first shielding part 201 with the Black Shield Mask (BSM) can prevent the obliquely irradiated light from being directed toward the Black Shield Mask (BSM) and entering the channel part 301 after being reflected by the Black Shield Mask (BSM), which further prevents the photoelectric effect of the channel part 301.

As shown in FIGS. 2 to 8, in some embodiments of the present disclosure, the shielding structure 20 further includes a second shielding part 202, the second shielding part 202 is coupled to the first shielding part 201, the second shielding part 202 is located at the side of the first insulating layer distal to the base substrate 10, and at least part of the orthographic projection of the second shielding part 202 onto the base substrate 10 is located at the periphery of the orthographic projection of the channel part 301 onto the base substrate 10.

For example, the second shielding part 202 extends on a surface of the first insulating layer distal to the base substrate 10.

For example, the second shielding part 202 is coupled to each one of the first shielding parts 201 included in the shielding structure 20 to which it belongs.

For example, in the same shielding structure 20, at least part of the orthographic projection of the first shielding part 201 onto the base substrate 10 overlaps with the orthographic projection of the second shielding part 202 onto the base substrate 10.

For example, in the same shielding structure 20, at least part of the first shielding part 201 is located between the second shielding part 202 and the base substrate 10.

For example, in the same shielding structure 20, the entire first shielding part 201 is located between the second shielding part 202 and the base substrate 10.

The above-mentioned arrangement enables the second shielding part 202 to shield the channel part 301, reducing the exposure of the channel part 301 to external light, thus improving the photoelectric effect of the channel part 301.

As shown in FIGS. 2 to 8, in some embodiments of the present disclosure, the orthographic projection of the second shielding part 202 onto the base substrate 10 overlaps at least partially with the orthographic projection of the channel part 301 onto the base substrate 10.

The above-mentioned arrangement enables the second shielding part 202 to shield the channel part 301, reducing the exposure of the channel part 301 to external light, thus improving the photoelectric effect of the channel part 301.

As shown in FIG. 8, in some embodiments of the present disclosure, the transistor structure TFT includes a gate layer GT, at least part of the gate layer GT is reused as the second shielding part 202.

For example, the first shielding part 201 is coupled to the gate layer GT.

For example, the first shielding part 201 is coupled to each of the gate layer GT and the Black Shield Mask (BSM) in the display substrate. The channel part 301 is located between the gate layer GT and the Black Shield Mask (BSM).

For example, the light-shielding structure includes two first shielding parts 201 arranged oppositely, and the orthographic projection of the channel part 301 onto the base substrate 10 is located between the orthographic projections of the two first shielding parts 201 onto the base substrate 10. Each of the two first shielding parts 201 is coupled to the gate layer GT. This arrangement better blocks the light from entering the channel part 301.

The above-mentioned arrangement implements the second shielding part 202 using a known structure, without the need for an additional second shielding part 202, thus avoiding any impact on the transmittance of the display substrate.

As shown in FIG. 7, in some embodiments of the present disclosure, the display substrate further includes a power line VDD, and at least part of the power line VDD is reused as the second shielding part 202.

For example, the first shielding part 201 is coupled to the power line VDD.

The above-mentioned arrangement implements the second shielding part 202 using a known structure, without the need for an additional second shielding part 202, thus avoiding any impact on the transmittance of the display substrate.

The above arrangement enables that the first shielding part 201 has a same stable potential as the power line VDD, thereby avoiding the first shielding part 201 being in a floating state. In some embodiments of the present disclosure, the display substrate further includes a data line, which is reused as the second shielding part 202.

In some embodiments of the present disclosure, the display substrate further includes a conductive connection part, which is reused as the second shielding part 202.

The above-mentioned arrangement implements the second shielding part 202 using a known structure, without the need for an additional second shielding part 202, thus avoiding any impact on the transmittance of the display substrate.

In some embodiments of the present disclosure, the display substrate includes a first gate insulating layer GI1, a first gate metal layer gate1, a second gate insulating layer GI2, a second gate metal layer gate2, an interlayer insulating layer ILD, a first source-drain metal layer SD1, a passivation layer PVX, a first planarization layer PLN1, a second source-drain metal layer SD2, a second planarization layer PLN2 and an anode layer that are laminated sequentially in that order on the base substrate 10 in a direction away from the base substrate 10; the channel part 301 is located between the first gate insulating layer GI1 and the base substrate 10;

the second shielding part 202 is arranged in a same layer and made of a same material as at least one of the first gate metal layer gate1, the second gate metal layer gate2, the first source-drain metal layer SD1, the second source-drain metal layer SD2 or the anode layer.

For example, the display substrate further includes a Pixel Defining Layer (PDL) and a spacer (PS).

The second shielding part 202 is arranged in a same layer and made of a same material as a known film layer in the display substrate, allowing the second shielding part 202 to be formed simultaneously with the known film layer in the display substrate during a same patterning process. This avoids introducing an additional patterning process for forming second shielding layer, thereby effectively simplifying the manufacturing process of the display substrate and reducing production costs.

As shown in FIGS. 2 to 8, in some embodiments of the present disclosure, the first shielding part 201 and the second shielding part 202 are formed as an integrated structure.

The above arrangement enables the first shielding part 201 to be formed simultaneously with the second shielding part 202 during a same patterning process, thereby effectively simplifying the manufacturing process of the display substrate and reducing production costs.

As shown in FIGS. 2 to 8, in some embodiments of the present disclosure, the first insulating layer includes at least one of the first gate insulating layer GI1, the second gate insulating layer GI2, the interlayer insulating layer ILD, the passivation layer PVX, the first planarization layer PLN1, or the second planarization layer PLN2.

For example, the first insulating layer includes at least two adjacent layers of the first gate insulating layer GI1, the second gate insulating layer GI2, the interlayer insulating layer ILD, the passivation layer PVX, the first planarization layer PLN1, or the second planarization layer PLN2. The first via hole penetrates through all the film layers included in the first insulating layer.

The above-mentioned arrangement enables the first via hole to be formed simultaneously with other functional via holes in the first insulating layer during a same patterning process. This avoids introducing an additional patterning process to form the first via hole, thereby effectively simplifying the manufacturing process of the display substrate and reducing production costs.

As shown in FIG. 8, in some embodiments of the present disclosure, the second shielding part 202 is arranged in a same layer and made of a same material as the first gate metal layer gate1, the first insulating layer includes the first gate insulating layer GI1, and the first via hole penetrates through the first gate insulating layer GI1.

In some embodiments of the present disclosure, the second shielding part 202 is arranged in a same layer and made of a same material as the second gate metal layer gate2, the first insulating layer includes the first gate insulating layer GI1 and the second gate insulating layer GI2, and the first via hole penetrates through the first gate insulating layer GI1 and the second gate insulating layer GI2.

As shown in FIGS. 4 to 6, in some embodiments of the present disclosure, the second shielding part 202 is arranged in a same layer and made of a same material as the first source-drain metal layer SD1, the first insulating layer includes the first gate insulating layer GI1, the second gate insulating layer GI2 and the interlayer insulating layer ILD, and the first via hole penetrates through the first gate insulating layer GI1, the second gate insulating layer GI2 and the interlayer insulating layer ILD.

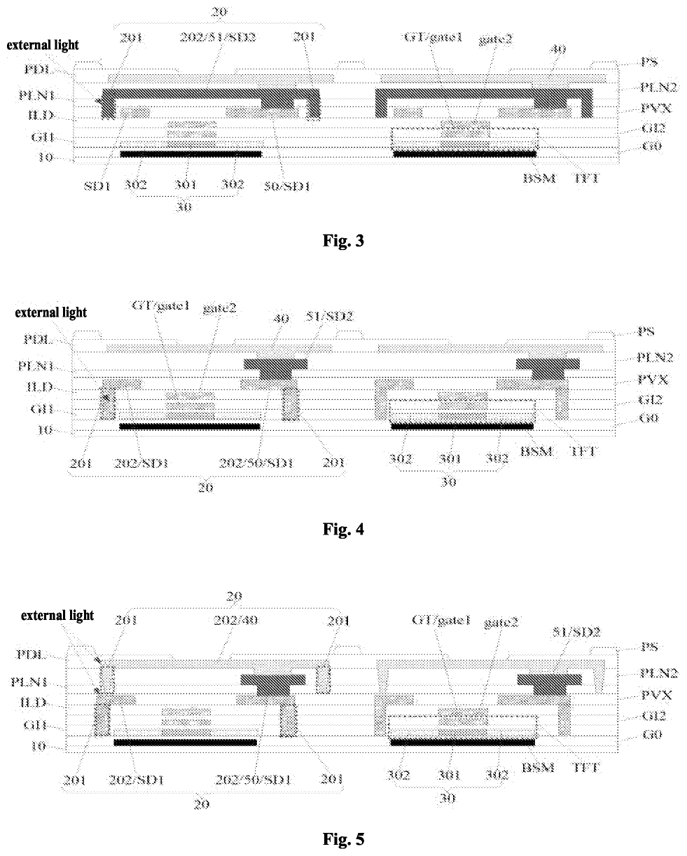

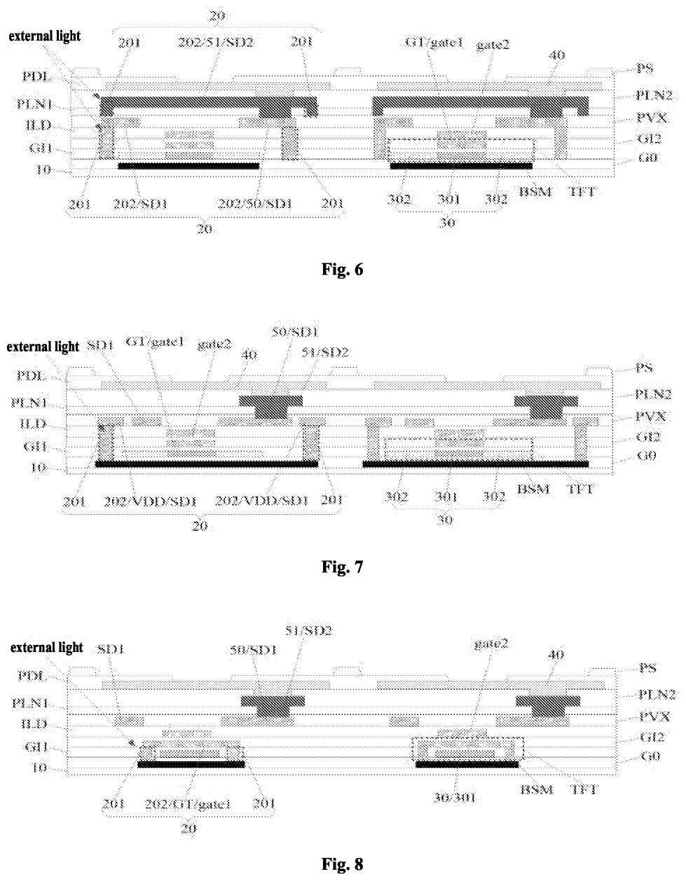

As shown in FIGS. 3 and 6, in some embodiments of the present disclosure, the second shielding part 202 is arranged in a same layer and made of a same material as the second source-drain metal layer SD2, the first insulating layer includes the first planarization layer PLN1, and the first via hole penetrates through the first planarization layer PLN1.

As shown in FIGS. 2 and 5, in some embodiments of the present disclosure, the second shielding part 202 is arranged in a same layer and made of a same material as the anode layer, the first insulating layer includes the first planarization layer PLN1 and the second planarization layer PLN2, and the first via hole penetrates through the first planarization layer PLN1 and the second planarization layer PLN2.

In the display substrate provided by the above embodiments, the second shielding part 202 can be formed simultaneously with the known film layer in the display substrate during a same patterning process. This avoids introducing an additional patterning process for forming the second shielding layer, thereby effectively simplifying the manufacturing process of the display substrate and reducing production costs. In the display substrate provided by the above embodiments, the first via hole can be formed simultaneously with other functional via holes in the first insulating layer during a same patterning process. This avoids introducing an additional patterning process to form the first via hole, thereby effectively simplifying the manufacturing process of the display substrate and reducing production costs.

In some embodiments of the present disclosure, the display substrate includes a plurality of sub-pixels, the sub-pixels include a sub-pixel driving circuit and a light-emitting element, the light-emitting element includes an anode pattern 40, the sub-pixel driving circuit is coupled to the anode pattern 40; the sub-pixel driving circuit includes the transistor structure TFT.

For example, the display substrate includes a plurality of sub-pixels, and the plurality of sub-pixel driving circuits included in the plurality of sub-pixels are arranged in an array. The plurality of sub-pixel driving circuits are divided into a plurality of rows of sub-pixel driving circuits and a plurality of columns of sub-pixel driving circuits. The plurality of rows of sub-pixel driving circuits are arranged in a second direction, and each row of sub-pixel driving circuits includes a plurality of sub-pixel driving circuits arranged in a first direction. The plurality of columns of sub-pixel driving circuits are arranged in a first direction, and each column of sub-pixel driving circuits includes a plurality of sub-pixel driving circuits arranged in a second direction. For example, the first direction and the second direction intersect. For example, the first direction is horizontal, and the second direction is vertical. Both the first direction and the second direction lie in a plane parallel to the base substrate 10.

For example, the sub-pixel includes a sub-pixel driving circuit and a light-emitting element. The sub-pixel driving circuit is coupled to the anode pattern 40 of the light-emitting element, and is configured to provide a driving signal to the light-emitting element to drive the light-emitting element to emit light.

For example, the sub-pixel driving circuit may adopt a circuit structure such as 7TIC (including 7 transistors and 1 storage capacitor), 8TIC (including 8 transistors and 1 storage capacitor), but the present disclosure is not limited thereto.

Taking the sub-pixel driving circuit adopting the 7TIC circuit structure as an example, the sub-pixel driving circuit includes the following structures:

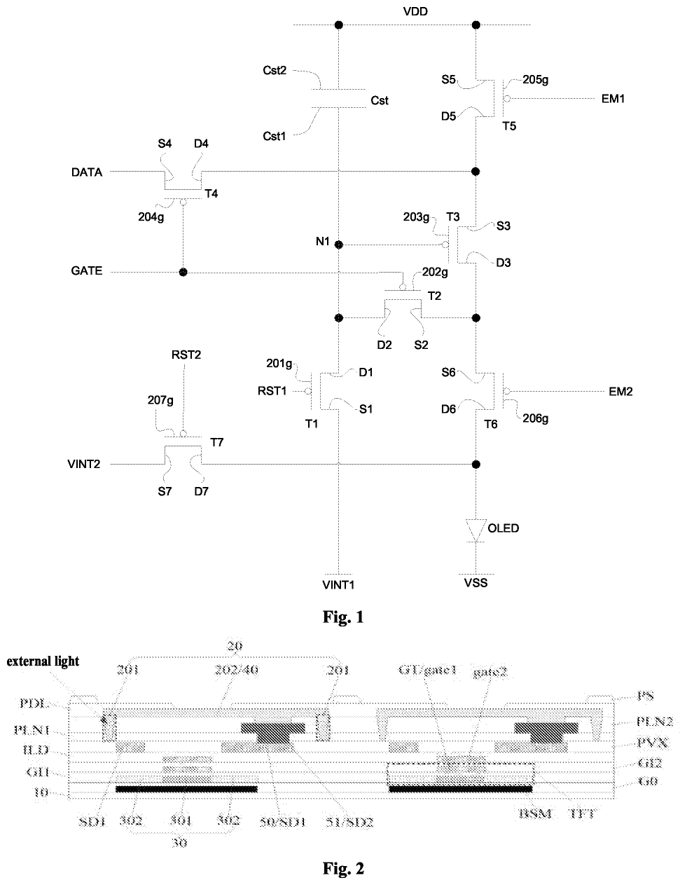

as shown in FIG. 1, the sub-pixel driving circuit includes: a first transistor T1, a second transistor T2, a third transistor T3, a fourth transistor T4, a fifth transistor T5, a sixth transistor T6, a seventh transistor T7 and a storage capacitor Cst; the first transistor T1, the second transistor T2, the third transistor T3, the fourth transistor T4, the fifth transistor T5, the sixth transistor T6, and the seventh transistor T7 may all be P-type transistors.

The gate electrode 201g of the first transistor T1 is coupled to the corresponding first reset signal line RST1, the source electrode S1 of the first transistor T1 is coupled to the corresponding first initialization signal line VINT1, and the drain electrode D1 of the first transistor T1 is coupled to the gate electrode 203g of the third transistor T3.

The gate electrode 202g of the second transistor T2 is coupled to the corresponding gate scanning line GATE, the source electrode S2 of the second transistor T2 is coupled to the drain electrode D3 of the third transistor T3, and the drain electrode D2 of the second transistor T2 is coupled to the gate electrode 203g of the third transistor T3.

The gate electrode 204g of the fourth transistor T4 is coupled to the corresponding gate scanning line GATE, the source electrode S4 of the fourth transistor T4 is coupled to the corresponding data line DATA, and the drain electrode D4 of the fourth transistor T4 is coupled to the source electrode S3 of the third transistor T3.

The gate electrode 205g of the fifth transistor T5 is coupled to the corresponding first light-emitting control signal line EM1, the source electrode S5 of the fifth transistor T5 is coupled to the corresponding power line VDD, and the drain electrode D5 of the fifth transistor T5 is coupled to the source electrode S3 of the third transistor T3.

The gate electrode 206g of the sixth transistor T6 is coupled to the corresponding second light-emitting control signal line EM2, the source electrode S6 of the sixth transistor T6 is coupled to the drain electrode D3 of the third transistor T3, and the drain electrode D6 of the sixth transistor T6 is coupled to the anode of the light-emitting element OLED.

The gate electrode 207g of the seventh transistor T7 is coupled to the second reset signal line RST2, the drain electrode D7 of the seventh transistor T7 is coupled to the first anode 501 of the light-emitting element OLED, and the source electrode S7 of the seventh transistor T7 is coupled to the corresponding second initialization signal line VINT2.

A first plate Cst1 of the storage capacitor Cst is coupled to the gate electrode 203g of the third transistor T3, so the gate electrode 203g of the third transistor T3 may be directly reused as the first plate Cst1 of the storage capacitor Cst, and a second plate Cst2 of the storage capacitor Cst is coupled to the corresponding power line VDD.

For example, the sub-pixel driving circuit includes the transistor structure TFT, which may be at least one of the first transistor T1, the second transistor T2, the third transistor T3, the fourth transistor T4, the fifth transistor T5, the sixth transistor T6 or the seventh transistor T7.

The above-mentioned arrangement avoids the photoelectric effect of the channel part 301 of the transistor structure TFT included in the sub-pixel driving circuit, thereby improving the stability of the sub-pixel driving circuit, and ensuring the display yield of the display substrate.

In some embodiments of the present disclosure, the sub-pixel driving circuit includes a driving transistor (i.e., a third transistor T3) and a compensation transistor (i.e., a second transistor T2), a first electrode of the compensation transistor is coupled to a second electrode of the driving transistor, and a second electrode of the compensation transistor is coupled to a gate electrode of the driving transistor; the transistor structure TFT includes the compensation transistor.

The above arrangement enables the first shielding part 201 to shield the channel part 301 of the compensation transistor, especially increasing the shielding of light incident at large oblique angles. This reduces the exposure of external light to the channel part 301 of the compensation transistor, thereby improving the photoelectric effect of the channel part 301 of the compensation transistor. When the transistor structure TFT is applied to the compensation transistor in the green sub-pixel, it prevents the problem of the leakage current of the green sub-pixel being greater than that of the red sub-pixel and the blue sub-pixel due to the photoelectric effect. This ensures the green light brightness of the green sub-pixel, and avoids the problem such as the area appearing pink or purple under strong light in the white screen of the display substrate.

In some embodiments of the present disclosure, the display substrate includes an initialization signal line (i.e., the above-mentioned first initialization signal line VINT1), the sub-pixel driving circuit further includes a first reset transistor (i.e., the above-mentioned first transistor T1), a first electrode of the first reset transistor is coupled to the initialization signal line, and a second electrode of the first reset transistor is coupled to the gate electrode of the driving transistor; the transistor structure TFT includes the first reset transistor.

The above arrangement enables the first shielding part 201 to shield the channel part 301 of the first reset transistor, especially increasing the shielding of light incident at large oblique angles. This reduces the exposure of external light to the channel part 301 of the first reset transistor, thereby improving the photoelectric effect of the channel part 301 of the first reset transistor. When the transistor structure TFT is applied to the first reset transistor in the green sub-pixel, it prevents the problem of the leakage current of the green sub-pixel being greater than that of the red sub-pixel and the blue sub-pixel due to the photoelectric effect. This ensures the green light brightness of the green sub-pixel, and avoids the problem such as the area appearing pink or purple under strong light in the white screen of the display substrate.

As shown in FIGS. 3 to 6, in some embodiments of the present disclosure, the sub-pixel driving circuit further includes a light-emitting control transistor (i.e., the aforementioned sixth transistor T6), a first conductive connection part 50, and a second conductive connection part 51. A first electrode of the light-emitting control transistor is coupled to a second electrode of the driving transistor, and a second electrode of the light-emitting control transistor is coupled to the anode pattern 40 through the first conductive connection part 50 and the second conductive connection part 51 sequentially in that order;

at least one of the first conductive connection part 50 and the second conductive connection part 51 is reused as the second shielding part 202.

For example, the first conductive connection part 50 is reused as the second shielding part 202. The light-shielding structure includes two first shielding parts 201 arranged oppositely. The orthographic projection of the channel part 301 onto the base substrate 10 is located between the orthographic projections of the two first shielding parts 201 onto the base substrate 10. Each of the two first shielding parts 201 is coupled to the first conductive connection part 50.

For example, the first shielding part 201 is located between the first conductive connection part 50 and the base substrate 10.

For example, a via hole process is used to form a first via hole penetrating through the interlayer insulating layer ILD, the first gate insulating layer GI1 and the second gate insulating layer GI2. The first via hole is an alignment hole, in which the first shielding part 201 is formed inside the hole, so that the first shielding part 201 and the first conductive connection part 50 jointly form an umbrella-like structure, blocking oblique light from entering the channel part 301, reducing the photoelectric effect of the channel part 301, and lowering the leakage current of the transistor structure TFT. The above-mentioned arrangement reuses the first conductive connection part 50 as the second shielding part 202 without increasing the size of the first conductive connection part 50, thus not affecting the transmittance of the display substrate. The above-mentioned arrangement implements the second shielding part 202 using a known structure, without the need for an additional second shielding part 202, thus avoiding any impact on the transmittance of the display substrate.

For example, the second shielding part 202 includes two independent first and second parts, and the first conductive connection part 50 is reused as the first part. The light-shielding structure includes two first shielding parts 201 arranged oppositely, and the orthographic projection of the channel part 301 onto the base substrate 10 is located between the orthographic projections of the two first shielding parts 201 onto the base substrate 10. One of the first shielding parts 201 is coupled to the first conductive connection part 50, and the other first shielding part 201 is coupled to the second part. For example, the first part is arranged in a same layer and made of a same material as the second part.

The above-mentioned arrangement enables the first shielding part 201, the first part and the second part, to jointly form a bilateral wrapping structure, blocking oblique light from entering the channel part 301, reducing the photoelectric effect of the channel part 301, and lowering the leakage current of the transistor structure TFT. The above-mentioned arrangement reuses the first conductive connection part 50 as the first part without increasing the size of the first conductive connection part 50, thus not affecting the transmittance of the display substrate. The above-mentioned arrangement implements the second shielding part 202 using a known structure, thus avoiding any impact on the transmittance of the display substrate.

For example, the second conductive connection part 51 is reused as the second shielding part 202, and the light-shielding structure includes two first shielding parts 201 arranged oppositely, and the orthographic projection of the channel part 301 onto the base substrate 10 is located between the orthographic projections of the two first shielding parts 201 onto the base substrate 10. Each of the two first shielding parts 201 is coupled to the second conductive connection part 51.

For example, the first shielding part 201 is located between the second conductive connection part 51 and the base substrate 10.

For example, a patterning process is used to form a first via hole penetrating through the passivation layer PVX and the first planarization layer PLN1. The first via hole is a the alignment hole, in which the first shielding part 201 is formed inside the hole, so that the first shielding part 201 and the second conductive connection part 51 jointly form an umbrella-like structure, blocking oblique light from entering the channel part 301, reducing the photoelectric effect of the channel part 301, and lowering the leakage current of the transistor structure TFT.

The above-mentioned arrangement reuses the second conductive connection part 51 as the second shielding part 202 without increasing the size of the second conductive connection part 51, thus not affecting the transmittance of the display substrate. The above-mentioned arrangement implements the second shielding part 202 using a known structure, without the need for an additional second shielding part 202, thus avoiding any impact on the transmittance of the display substrate.

As shown in FIGS. 2 and 5, in some embodiments of the present disclosure, the anode pattern 40 is reused as the second shielding part 202.

For example, the light-shielding structure includes two first shielding parts 201 arranged oppositely, and the orthographic projection of the channel part 301 onto the base substrate 10 is located between the orthographic projections of the two first shielding parts 201 onto the base substrate 10. Each one of the two first shielding parts 201 is coupled to the anode pattern 40.

For example, the first shielding part 201 is located between the anode pattern 40 and the base substrate 10.

For example, a patterning process is used to form a first via hole penetrating through the first planarization layer PLN1 and the second planarization layer PLN2, and the first via hole is an alignment hole, in which the first shielding part 201 is formed inside the hole, so that the first shielding part 201 and the anode pattern 40 jointly form an umbrella-like structure, blocking oblique light from entering the channel part 301, reducing the photoelectric effect of the channel part 301, and lowering the leakage current of the transistor structure TFT.

The above-mentioned anode pattern 40 is reused as the second shielding part 202 without increasing the size of the anode pattern 40, thus not affecting the transmittance of the display substrate.

The above-mentioned arrangement implements the second shielding part 202 using a known structure, without the need for an additional second shielding part 202, thus avoiding any impact on the transmittance of the display substrate.

As shown in FIGS. 5 and 6, in some embodiments of the present disclosure, the transistor structure TFT corresponds to at least two shielding structures 20, and the at least two shielding structures 20 are sequentially arranged in a direction perpendicular to the base substrate 10.

For example, in the at least two shielding structures 20, each shielding structure 20 is located in a different film layer. The first shielding part 201 included in each shielding structure 20 penetrates through different insulating layers.

The above-mentioned arrangement that the transistor structure TFT corresponds to at least two shielding structures 20 further enhances the light-blocking effect of the shielding structures 20, further preventing the occurrence of the photoelectric effect in the channel part 301.

The embodiments of the present disclosure further provide a display device, including the display substrate provided by the above embodiment.

For example, the display device includes an active matrix organic light-emitting diode display device, but the present disclosure is not limited thereto.

It should be noted that the display device may be: any product or component with a display function, such as a TV, a monitor, a digital photo frame, a mobile phone, a tablet computer, etc., wherein the display device further includes a flexible circuit board, a printed circuit board, a backplane, and other components.

In the display substrate provided by the above embodiments, the shielding structure includes a first shielding part, at least part of the first shielding part extends in a direction perpendicular to the base substrate. An orthographic projection of the first shielding part onto the base substrate is located at the periphery of an orthographic projection of the corresponding channel part of the transistor structure onto the base substrate. The above-mentioned arrangement enables the first shielding part to shield the channel part, especially increasing the shielding of light incident at a large oblique angle. This reduces the exposure of external light to the channel part, thereby improving the photoelectric effect of the channel part. Moreover, the first shielding part extends in a direction perpendicular to the base substrate, and it does not affect the transmittance of the display substrate.

In the display substrate provided by the embodiments of the present disclosure, when the transistor structure is applied to the green sub-pixel as a compensation transistor, it prevents the problem of the leakage current of the green sub-pixel being greater than that of the red sub-pixel and the blue sub-pixel due to the photoelectric effect. This ensures the green light brightness of the green sub-pixel, and avoids the problem such as the area appearing pink or purple under strong light in the white screen of the display substrate. In the display substrate provided by the embodiments of the present disclosure, when strong light is irradiated obliquely, the light will not enter the channel part from the side, avoiding the problem of aggravation of the reddish and purple phenomenon of the display product. At the same time, in the display substrate provided by the embodiments of the present disclosure, it is possible to prevent the obliquely irradiated light from irradiating the film layer (such as light-shielding layer (also known as Black Shield Mask (BSM))) located between the channel part and the base substrate, and avoid the light from entering the channel part after being reflected by the film layer, further avoiding the photoelectric effect.

The display device provided by the embodiments of the present disclosure also has the above-mentioned beneficial effects when including the display substrate provided by the above-mentioned embodiments, which will not be described in detail herein.

It should be noted that the “same layer” in the embodiments of the present disclosure may refer to a film layer on a same structural layer. Or, for example, the film layer in the same layer may be a film layer formed using a same deposition process to create a specific pattern, and then the film layer is patterned by a same mask through a single patterning process to form a layer structure. Depending on the specific pattern, the single patterning process may include multiple exposure, development or etching processes, and the specific pattern in the resulting layer structure may be continuous or discontinuous. These specific patterns may also be at different heights or have different thicknesses.

In the method embodiments of the present disclosure, the serial numbers of the steps are not used to limit the order of the steps. For those of ordinary skill in the art, changes in the order of the steps without making creative efforts, also fall within the scope of this disclosure.

It should be noted that the embodiments in this specification is described in a progressive manner, and the same and similar parts among the embodiments can be referred to each other, with the focus of each embodiment being the differences from other embodiments. In particular, for the method embodiment, since it is basically similar to the product embodiment, the description is relatively simple, and the relevant parts can be referred to the description of the product embodiment.

Unless otherwise defined, the technical terms or scientific terms used in the present disclosure should be understood by those of ordinary skill in the art. “First”, “second” and similar words used in the present disclosure do not indicate any order, quantity or importance, but are merely used to distinguish different components. “Including” or “comprising” and similar terms are intended to indicate that the elements or objects preceding these terms encompass the elements or objects listed thereafter and their equivalents, without excluding other elements or objects. “Connecting”, “coupling” or “connected” and similar terms are not limited to physical or mechanical connections, but can include electrical connections, whether direct or indirect. “Up”, “down”, “left”, “right” and the like are solely used to describe relative positional relationships. When the absolute position of the described object changes, the relative positional relationship may also change accordingly.

It is understood that when an element such as a layer, film, region or substrate is referred to as being “on” or “under” another element, the element may be “directly” “on” or “under” another element, or there may be an intermediate element in between.

In the description of the above embodiments, specific features, structures, materials or characteristics may be combined in a suitable manner in any one or more embodiments or examples.

The above description is merely about specific embodiments of the present disclosure, and the protection scope of the present disclosure is not limited thereto. Any modifications or substitutions easily conceived by those of ordinary skill in the art within the technical scope disclosed in the present disclosure shall also fall within the protection scope of the present disclosure. Therefore, the protection scope of the present disclosure shall be determined by the scope of the claims.

1. A display substrate, comprising: a base substrate, a transistor structure and a shielding structure, wherein the transistor structure and the shielding structure are both arranged on the base substrate, the shielding structure comprises a first shielding part, at least part of the first shielding part extends in a direction perpendicular to the base substrate, and an orthographic projection of the first shielding part onto the base substrate is located at a periphery of an orthographic projection of a channel part of the corresponding transistor structure onto the base substrate.

2. The display substrate according to claim 1, wherein the display substrate comprises a first insulating layer located at a side of the channel part distal to the base substrate, the first insulating layer comprises a first via hole, and at least part of the first shielding part is located in the first via hole.

3. The display substrate according to claim 2, wherein the display substrate comprises a second insulating layer located at a side of the channel part proximate to the base substrate, the second insulating layer comprises a second via hole, and at least part of the first shielding part is located in the second via hole.

4. The display substrate according to claim 1, wherein the shielding structure comprises two first shielding parts, and the orthographic projection of the channel part onto the base substrate is located between the orthographic projections of the two first shielding parts onto the base substrate.

5. The display substrate according to claim 4, wherein the transistor structure comprises an active layer, the active layer comprises the channel part and two conductor parts, the channel part is located between the two conductor parts, and the orthographic projection of the first shielding part onto the base substrate extends in an extension direction of at least part of a boundary of an orthographic projection of the conductor part onto the base substrate.

6. The display substrate according to claim 1, wherein
the orthographic projection of the channel part onto the base substrate is surrounded by the orthographic projection of the first shielding part onto the base-substrate substrate; or
the display substrate further comprises a Black Shield Mask (BSM), wherein the BSM is located between the channel part and the base substrate, and the first shielding part is coupled to the BSM; or
the transistor structure corresponds to at least two shielding structures, and the at least two shielding structures are sequentially arranged in a direction perpendicular to the base substrate.

7.-8. (canceled)

9. The display substrate according to claim 2, wherein the shielding structure further comprises a second shielding part, the second shielding part is coupled to the first shielding part, the second shielding part is located at the side of the first insulating layer distal to the base substrate, and at least part of an orthographic projection of the second shielding part onto the base substrate is located at the periphery of the orthographic projection of the channel part onto the base substrate.

10. The display substrate according to claim 9, wherein the orthographic projection of the second shielding part onto the base substrate overlaps at least partially with the orthographic projection of the channel part onto the base substrate.

11. The display substrate according to claim 9, wherein the transistor structure comprises a gate layer, and at least part of the gate layer is reused as the second shielding part.

12. The display substrate according to claim 9, wherein the display substrate further comprises a power line, and at least part of the power line is reused as the second shielding part.

13. The display substrate according to claim 9, wherein the display substrate comprises a first gate insulating layer, a first gate metal layer, a second gate insulating layer, a second gate metal layer, an interlayer insulating layer, a first source-drain metal layer, a passivation layer, a first planarization layer, a second source-drain metal layer, a second planarization layer and an anode layer that are laminated sequentially in that order on the base substrate in a direction away from the base substrate; the channel part is located between the first gate insulating layer and the base substrate;
the second shielding part is arranged in a same layer and made of a same material as at least one of the first gate metal layer, the second gate metal layer, the first source-drain metal layer, the second source-drain metal layer or the anode layer.

14. The display substrate according to claim 13, wherein the first shielding part and the second shielding part are formed as an integrated structure.

15. The display substrate according to claim 13, wherein the first insulating layer comprises at least one of the first gate insulating layer, the second gate insulating layer, the interlayer insulating layer, the passivation layer, the first planarization layer or the second planarization layer.

16. The display substrate according to claim 15, wherein the second shielding part is arranged in a same layer and made of a same material as the first gate metal layer, the first insulating layer comprises the first gate insulating layer, and the first via hole penetrates through the first gate insulating layer.

17. The display substrate according to claim 15, wherein the second shielding part is arranged in a same layer and made of a same material as the second gate metal layer, the first insulating layer comprises the first gate insulating layer and the second gate insulating layer, and the first via hole penetrates through the first gate insulating layer and the second gate insulating layer.

18. The display substrate according to claim 15, wherein the second shielding part is arranged in a same layer and made of a same material as the first source-drain metal layer, the first insulating layer comprises the first gate insulating layer, the second gate insulating layer and the interlayer insulating layer, and the first via hole penetrates through the first gate insulating layer, the second gate insulating layer and the interlayer insulating layer.

19. The display substrate according to claim 15, wherein the second shielding part is arranged in a same layer and made of a same material as the second source-drain metal layer, the first insulating layer comprises the first planarization layer, and the first via hole penetrates through the first planarization layer.

20. The display substrate according to claim 15, wherein the second shielding part is arranged in a same layer and made of a same material as the anode layer, the first insulating layer comprises the first planarization layer and the second planarization layer, and the first via hole penetrates through the first planarization layer and the second planarization layer.

21. The display substrate according to claim 9, wherein the display substrate comprises a plurality of sub-pixels, the sub-pixels comprise a sub-pixel driving circuit and a light-emitting element, the light-emitting element comprises an anode pattern, the sub-pixel driving circuit is coupled to the anode pattern; the sub-pixel driving circuit comprises the transistor structure;
the anode pattern is reused as the second shielding part.

22. (canceled)

23. A display device comprising the display substrate according to claim 1.
